(19) United States
(12) Patent Application Publication
(10) Pub. No.: US 2017/0110244 A1
(43) Pub. Date: Apr. 20, 2017

(54) CIRCUIT BOARD FOR RADIO TRANSCEIVING AND METHOD FOR MANUFACTURING SAME

(71) Applicants: FuKui Precision Component (Shenzhen) Co., Ltd., Shenzhen (CN); HongQiSheng Precision Electronics (QinHuangDao) Co.,Ltd., Qinhuangdao (CN); Zhen Ding Technology Co., Ltd., Taoyuan (TW)

(72) Inventors: XIAN-QIN HU, Qinhuangdao (CN); FU-YUN SHEN, Shenzhen (CN); MING-JAAN HO, New Taipei (TW); YI-QIANG ZHUANG, Shenzhen (CN)

(21) Appl. No.: 14/928,530

(22) Filed: Oct. 30, 2015

(30) Foreign Application Priority Data
Oct. 16, 2015 (CN) 201510669718.4

(51) Int. Cl. H01F 38/14; H01F 41/04; H01F 27/28; H05K 3/06

(52) U.S. Cl. CPC H01F 38/14; H05K 3/06; H01F 41/041; H01F 27/2804

(57) ABSTRACT

A circuit board for radio transceiving includes a flexible base and an inductance unit. The flexible base has a first conductive hole. The inductance unit includes a first inductance coil located at a first side of the flexible base and a second inductance coil located at an opposite side of the flexible base from the first inductance coil. The first inductance coil surrounds the first conductive hole and extends in a spiral direction and turn-by-turn into the first conductive hole. The second inductance coil surrounds the first conductive hole and extends in a spiral direction and turn-by-turn out from the first conductive hole. The first inductance coil and the second inductance coil are electrically connected with each other via the first conductive hole through the flexible base.

### FIELD

The subject matter herein generally relates to circuit board manufacture.

### BACKGROUND

An antenna, such as for wireless fidelity (WI-FI), BLUETOOTH, Global Positioning System (GPS), near field communication (NFC), code division multiple access (CDMA), or long term evolution (LTE), can have inductive components mounted on a printed circuit board. The discrete inductive components can be attached and mounted on the printed circuit board.

### BRIEF DESCRIPTION OF THE DRAWINGS

Implementations of the present technology will now be described, by way of example only, with reference to the attached figures.

FIG. 1 is an isometric view of an embodiment of an inductance unit integrated into a circuit board.

FIG. 2 is a cross sectional view of the circuit board taken along II-II line of FIG. 1.

FIG. 3 is a top plan view of the circuit board of FIG. 1.

FIG. 4 is a bottom view of the circuit board of FIG. 1.

FIG. 5 is a cross sectional view of the circuit board of FIG. 1, covered by first and second cover layers.

FIG. 6 is a flow chart of an embodiment of the manufacture of the circuit board of FIG. 1.

FIG. 7 is a cross sectional view of a flexible base with first and second conductive holes electrically connecting first and second back-to-back copper layers.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain parts have been exaggerated to better illustrate details and features of the present disclosure.

Several definitions that apply throughout this disclosure will now be presented.

The term “substantially” is defined to be essentially conforming to the particular dimension, shape, or other feature that the term modifies, such that the component or arrangement need not be exact. The term “comprising,” when utilized, means “including, but not necessarily limited to”; it specifically indicates open-ended inclusion or membership in the so-described combination, group, series and the like.

The present disclosure is described in relation to a circuit board for radio transceiving comprising a flexible base and an inductance unit. The flexible base has a first conductive hole. The inductance unit comprises a first inductance coil located at a first side of the flexible base and a second inductance coil located at an opposite side of the flexible base from the first inductance coil. The first inductance coil surrounds the first conductive hole and extends in a spiral direction and turn-by-turn into the first conductive hole. The second inductance coil surrounds the first conductive hole and extends in a spiral direction and turn-by-turn out from the first conductive hole. The first inductance coil and the second inductance coil are electrically connected with each other via the first conductive hole through the flexible base.

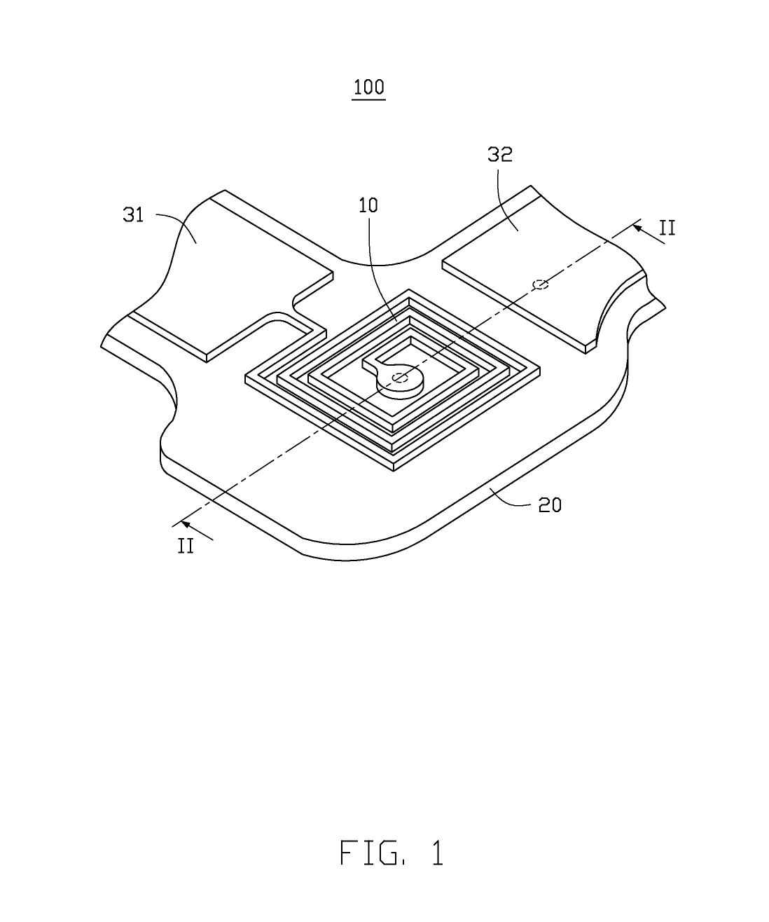

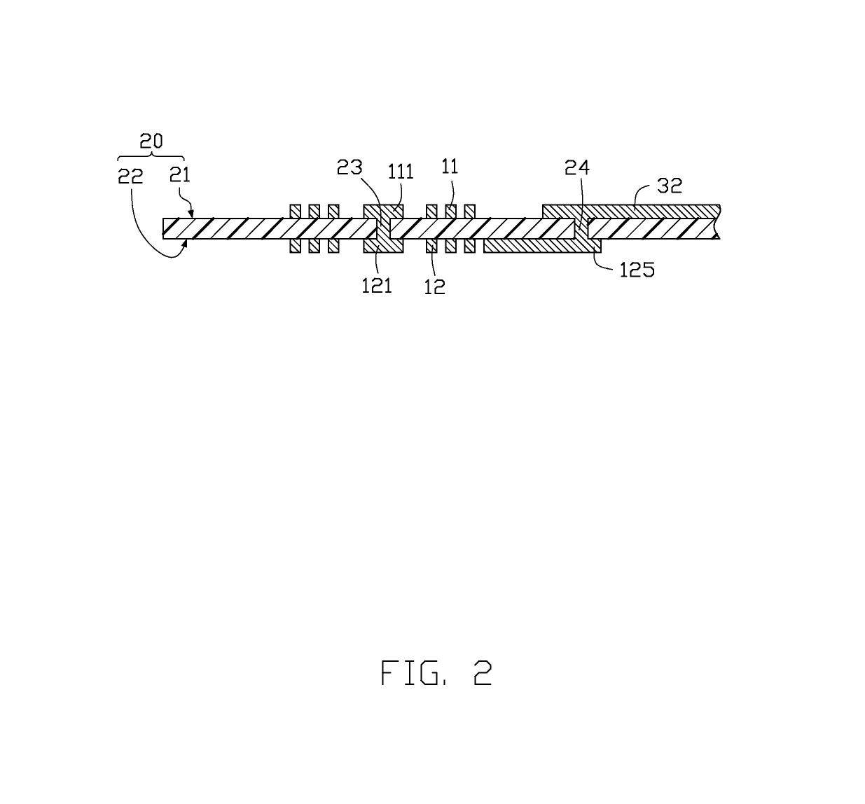

FIGS. 1 and 2 illustrate that a circuit board 100 includes an inductance unit 10, a flexible base 20, a first copper ground 31, and a second copper ground 32.

The flexible base 20 includes a first surface 21 and a second surface 22. The first surface 21 and the second surface 22 are opposite to each other. In at least one embodiment, the first surface 21 and the second surface 22 are substantially parallel to each other. The flexible base 20 can be made of materials chosen from Polymide, Polycarbonate, Polyetherimide, and Polyester.

The inductance unit 10 is located within an area of 1.8 mm*1.9 mm. In at least one embodiment, an inductance of the inductance unit 10 ranges from 43.12 nH to 52.49 nH. A direct-current (DC) resistance of the inductance unit 10 ranges from 0.208 ohm to 0.235 ohm. Quality factor of the inductance unit 10 ranges from 32.385 to 45.99. Self-resonant frequency (SRF) of the inductance unit 10 ranges from 829 MHz to 1089 MHZ. In at least one embodiment, the inductance unit 10 includes a first inductance coil 11 and a second inductance coil 12. The first inductance coil 11 and the second inductance coil 12 can be made of conductive metals, such as copper, silver, aluminum. In at least one embodiment, the first inductance coil 11 and the second inductance coil 12 are made of copper. The first inductance coil 11 and the second inductance coil 12 are located at opposite sides of the flexible base 20. In at least one embodiment, the first inductance coil 11 is located at the first surface 21. The second inductance coil is located at the second surface 22. The first inductance coil 11 and the second inductance coil 12 are electrically connected with each other via a conductive hole 23 through the flexible base 20.

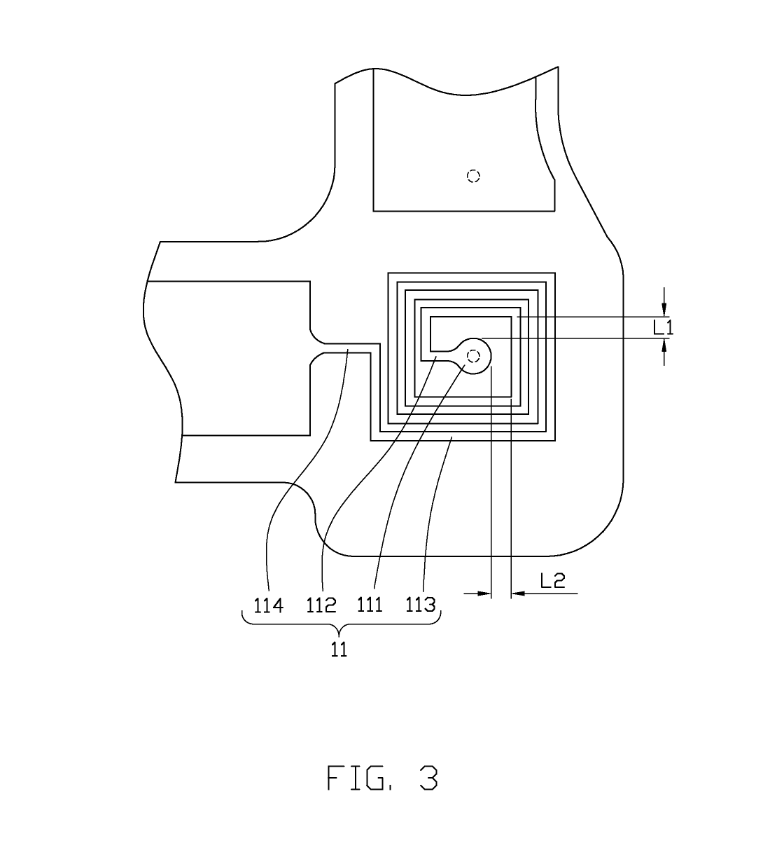

As illustrated in FIG. 3, the first inductance coil 11 surrounds the first conductive hole 23 and extends in a spiral direction and turn-by-turn to electrically connect to the first conductive hole 23. In at least one embodiment, the first inductance coil 11 includes a first pad 111, a first connecting portion 112, a first coil body 113, and a first ground portion 114. The first pad 111 is aligned with and electrically connected with the first conductive hole 23. In at least one embodiment, the first pad 111 is substantially located at a center of the first coil body 113. The first connecting portion 112 electrically connects the first pad 111 and the first coil body 113. In at least one embodiment, the first connecting portion 112 is substantially perpendicularly connected between the first pad 111 and the first coil body 113. The first ground portion 114 is electrically connected with an end of the first coil body 113 away from the first connecting portion 112. In at least one embodiment, the first ground portion 114 is substantially perpendicularly connected with the end of the first coil body 113 away from the first connecting portion 112. The first coil body 113 extends in a spiral direction from the first ground portion 114 into the first connecting portion 112. A distance between an inner circle of the first coil body 113 and the first pad 111 ranges from 0.05 mm to 0.15 mm. In at least one embodiment, a distance along a direction perpendicular to an extending direction of the first connecting portion 112, between the inner circle of the first coil body 113 and the first pad 111, is greater than that along the extending direction of the first connecting portion 112. In at least one embodiment, a distance L1 along a direction perpendicular to an extending direction of the first connecting portion 112, between the inner circle of the first coil body 113 and the first pad 111, is about 0.15 mm. A distance L2 along an extending direction of the first connecting portion 112, between the inner circle of the first coil body 113 and the first pad 111, is about 0.1 mm.

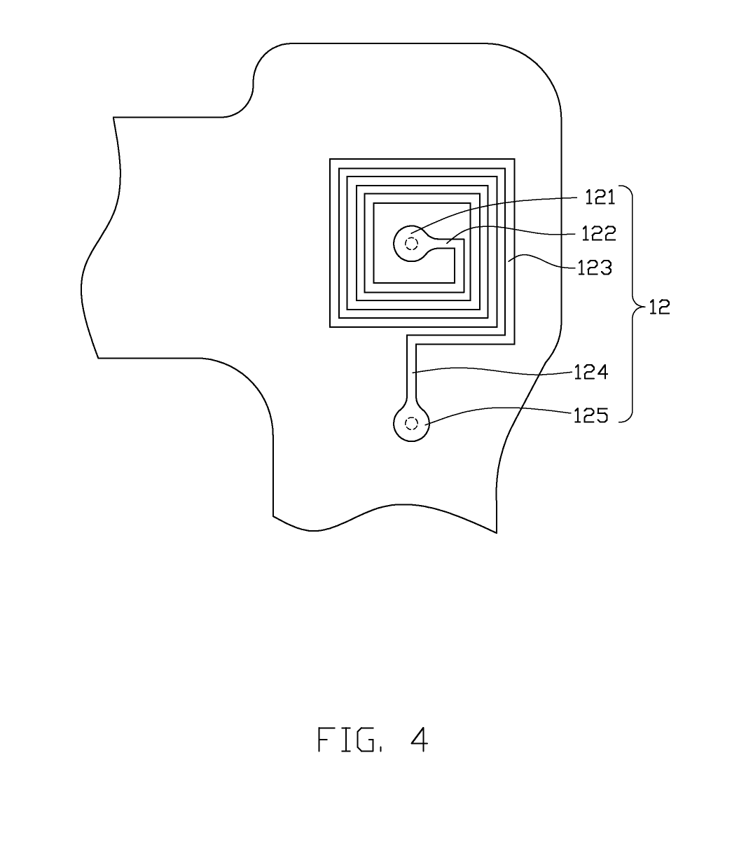

As illustrated in FIG. 4, the second inductance coil 12 surrounds the first conductive hole 23 and extends in a spiral direction and turn-by-turn out from the first conductive hole 23. In at least one embodiment, the second inductance coil 12 includes a second pad 121, a second connecting portion 122, a second coil body 123, a second ground portion 124, and a ground pad 125. Referring back to FIG. 2, the second pad 121 and the first pad 111 correspond to each other and are electrically connected via the first conductive hole 23. In at least one embodiment, the second pad 121 is substantially located at a center of the second coil body 123. The second connecting portion 122 electrically connects the second pad 121 and the second coil body 123. In at least one embodiment, the second connecting portion 122 is substantially perpendicularly connected between the second pad 121 and the second coil body 123. In at least one embodiment, the first connecting portion 112 and the second connecting portion 122 extend along opposite but parallel directions. The second coil body 123 extends in a spiral direction and turn-by-turn from the second connecting portion 121 out to the second ground portion 124. The second ground portion 124 electrically connects the ground pad 125 and an end of the second coil body 123 away from the second connecting portion 122. In at least one embodiment, the second ground portion 124 is substantially perpendicularly connected between the ground pad 125 and an end of the second coil body 123 away from the second connecting portion 122.

In at least one embodiment, directions of current flow in the first inductance coil 11 and in the second inductance coil 12 are the same to avoid interference between the first inductance coil 11 and the second inductance coil 12. In at least one embodiment, directions of current flow in the first inductance coil 11 and in the second inductance coil 12 are clockwise or counterclockwise projected through the circuit board. In at least one embodiment, a number of windings of the first coil body 113 is equal to a number of windings of the second coil body 123. A projection of the outlines of the first coil body 113 substantially coincides with the outlines of the second coil body 123.

Referring back to FIG. 1, the first copper ground 31, the second copper ground 32, and the first inductance coil 11 are located at the first surface 21 of the flexible base 20 and are in a same layer. The first inductance coil 11 is located between the first copper ground 31 and the second copper ground 32. In at least one embodiment, extension directions of the first copper ground 31 and the second copper ground 32 are perpendicular to each other. The first inductance coil 11 is located at an intersection of the first copper ground 31 and the second copper ground 32 as each is extended. The first ground portion 114 of the first inductance coil 11 is electrically connected to the first copper ground 31. The ground pad 125 of the second inductance coil 12 is electrically connected to the second copper ground 32 via a second conductive hole 24 through the flexible base 20.

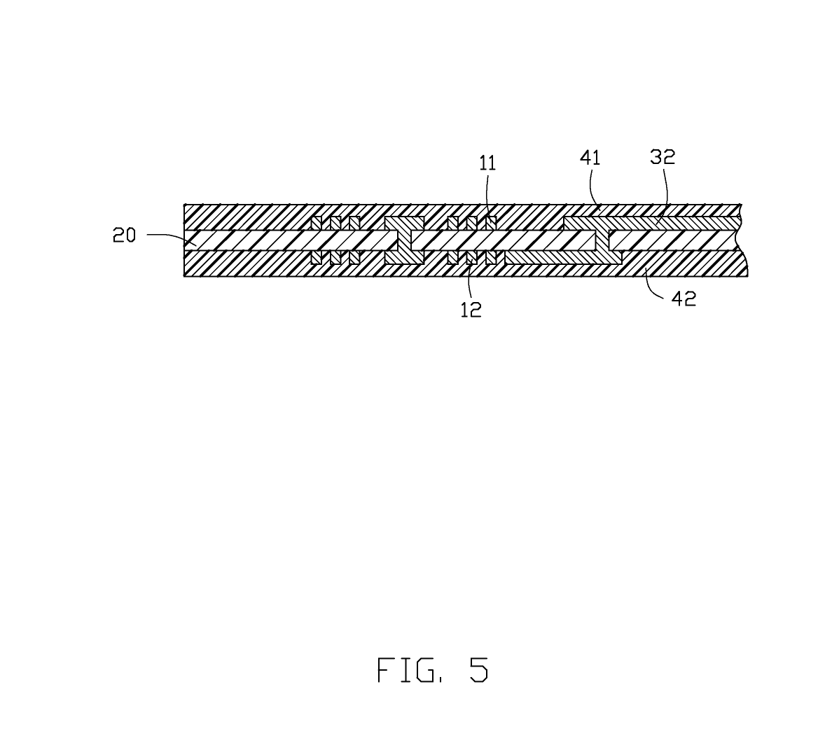

Referring to FIG. 5, in at least one embodiment, the circuit board 100 further includes a first cover layer 41 and a second cover layer 42. The first cover layer 41 covers the first copper ground 31, the first inductance coil 11, the second copper ground 32, and the remaining portions of the flexible base 20 which are exposed the first copper ground 31 and the second copper ground 32. The second cover layer 42 covers the second inductance coil 12 and the remaining and exposed portions of the flexible base 20.

In other embodiments, a projection of the first coil body 113 substantially complements the second coil body 123, that is, a direct projection of the windings of the first coil body 113 substantially coincides with intervals between the windings of the second inductance coil 12.

In other embodiment, numbers of windings of the first and second inductance bodies 113 and 123 are different.

In other embodiments, the first pad 111 and the second pad 121 can be omitted.

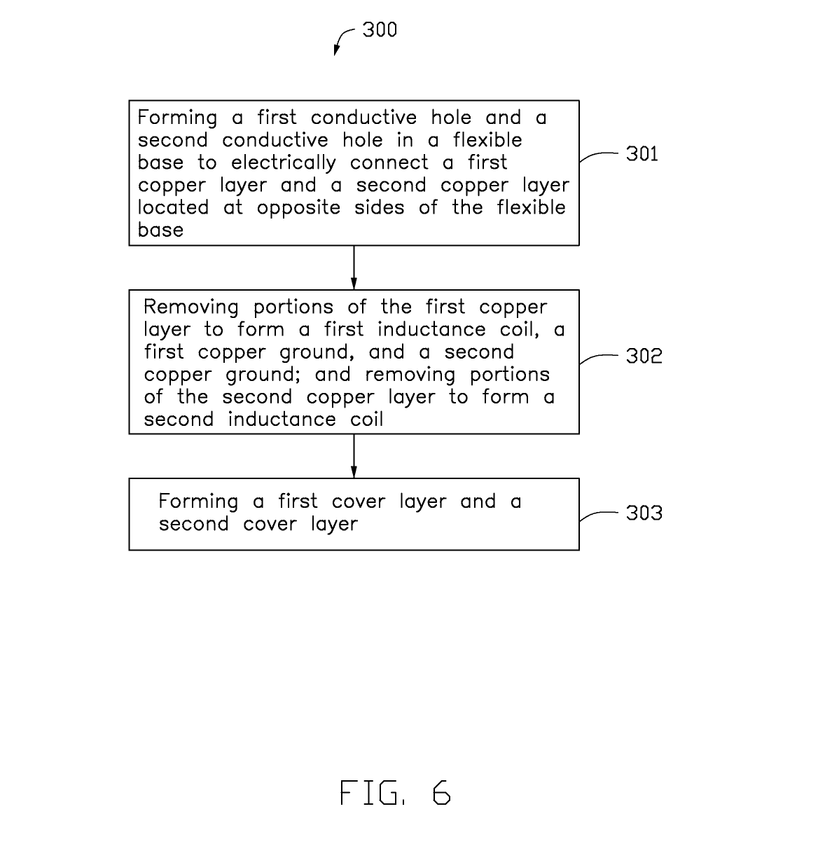

FIG. 6 illustrates a flowchart presented in accordance with an example embodiment. The example method 300 for manufacturing a circuit board 100 (shown in FIG. 1) is provided by way of example, as there are a variety of ways to carry out the method. Each block shown in FIG. 6 represents one or more processes, methods, or subroutines, carried out in the exemplary method 300. Additionally, the illustrated order of blocks is by example only and the order of the blocks can change. The exemplary method 300 can begin at block 301.

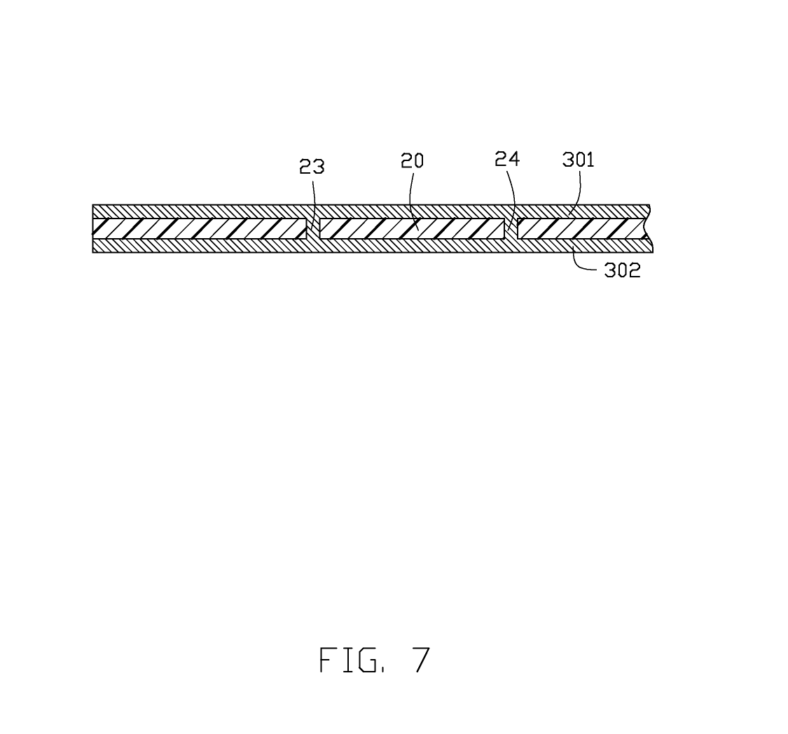

At block 301, referring to FIG. 7, a first conductive hole 23 and a second conductive hole 24 are formed in a flexible base 20 to electrically connect a first copper layer 301 and a second copper layer 302, such copper layers being located at opposite sides of the flexible base 20.

In at least one embodiment, the first conductive hole 23 and the second conductive hole 24 can be formed by drilling and plating.

At block 302, portions of the first copper layer 301 are removed to form a first inductance coil 11, a first copper ground 31, and a second copper ground 32. Portions of the second copper layer 302 are removed to form a second inductance coil 12.

Referring to FIG. 1, the first inductance coil 11 is located between the first copper ground 31 and the second copper ground 32. In at least one embodiment, extension directions of the first copper ground 31 and the second copper ground 32 are perpendicular to each other. The first inductance coil 11 is located at an intersection of the first copper ground 31 and the second copper ground 32 as extended.

Referring to FIG. 2, the first inductance coil 11 and the second inductance coil 12 are electrically connected to each other via the first conductive hole 23.

Referring to FIG. 3, the first inductance coil 11 surrounds the first conductive hole 23 and extends in a spiral direction and turn-by-turn into the first conductive hole 23. In at least one embodiment, the first inductance coil 11 includes a first pad 111, a first connecting portion 112, a first coil body 113, and a first ground portion 114. The first pad 111 is aligned with and electrically connected with first conductive hole 23. In at least one embodiment, the first pad 111 is substantially located at a center of the first coil body 113. The first connecting portion 112 is electrically connected between the first pad 111 and the first coil body 113. In at least one embodiment, the first connecting portion 112 is substantially perpendicularly connected between the first pad 111 and the first coil body 113. The first ground portion 114 is electrically connected between the first copper ground 31 and an end of the first coil body 113 away from the first connecting portion 112. In at least one embodiment, the first ground portion 114 is substantially perpendicularly connected with the end of the first coil body 113 away from the first connecting portion 112. The first coil body 113 extends in a spiral direction from the first ground portion 114 into the first connecting portion 112. A distance between an inner circle of the first coil body 113 and the first pad 111 ranges from 0.05 mm to 0.15 mm. In at least one embodiment, a distance along a direction perpendicular to an extending direction of the first connecting portion 112, between the inner circle of the first coil body 113 and the first pad 111, is greater than that along the extending direction of the first connecting portion 112. In at least one embodiment, a distance L1 along a direction perpendicular to an extending direction of the first connecting portion 112, between the inner circle of the first coil body 113 and the first pad 111, is about 0.15 mm. A distance L2 along an extending direction of the first connecting portion 112, between the inner circle of the first coil body 113 and the first pad 111, is about 0.1 mm.

Referring to FIG. 4, the second inductance coil 12 surrounds the first conductive hole 23 and extends in a spiral direction and turn-by-turn out from the first conductive hole 23. In at least one embodiment, the second inductance coil 12 includes a second pad 121, a second connecting portion 122, a second coil body 123, a second ground portion 124, and a ground pad 125. Referring to FIG. 2, the second pad 121 and the first pad 111 correspond to each other and are electrically connected via the first conductive hole 23. In other embodiment, the first pad 111 and the second pad 121 can be omitted, and the first connecting portion 112 and the second connecting portion 122 can be electrically connected via the first conductive hole 23. In at least one embodiment, the second pad 121 is substantially located at a center of the second coil body 123. The second connecting portion 122 electrically connects the second pad 121 and the second coil body 123. In at least one embodiment, the second connecting portion 122 is substantially perpendicularly connected between the second pad 121 and the second coil body 123. In at least one embodiment, the first connecting portion 112 and the second connecting portion 122 extend along opposite but parallel directions. The second coil body 123 extends in a spiral direction and turn-by-turn from the second connecting portion 121 out to the second ground portion 124. The second ground portion 124 is electrically connected between the ground pad 125 and an end of the second coil body 123 away from the second connecting portion 122. In at least one embodiment, the second ground portion 124 is substantially perpendicularly connected between the ground pad 125 and an end of the second coil body 123 away from the second connecting portion 122. Referring to FIG. 2, the ground pad 125 is electrically connected to the second copper ground 32 via the second conductive hole 24.

In at least one embodiment, the first copper layer 301 and the second copper layer 302 can be removed by image transferring and etching process.

At block 303, a first cover layer 41 and a second cover layer 42 are formed.

Referring to FIG. 5, the first cover layer 41 covers the first copper ground 31, the first inductance coil 11, the second copper ground 32, and the remaining portions of the flexible base 20 exposed from the first copper ground 31 and the second copper ground 32. The second cover layer 42 covers the second inductance coil 12 and the exposed remaining portions of the flexible base 20.

In other embodiments, block 303 can be omitted.

The inductance unit 10 is thus integrally formed in, and part of, the circuit board 100. That is, the inductance unit 10 is integrated in the circuit board 100, not for example soldered on the circuit board 100. Manufacturing time of the circuit board 100 is shorter, production efficiency improved, and size of a final product is reduced.

The embodiments shown and described above are only examples. Many details are often found in the art such as the other features of a circuit board integrated with an inductance unit and method for manufacturing a circuit board integrated with an inductance unit. Therefore, many such details are neither shown nor described. Even though numerous characteristics and advantages of the present technology have been set forth in the foregoing description, together with details of the structure and function of the present disclosure, the disclosure is illustrative only, and changes may be made in the details, especially in matters of shape, size, and arrangement of the parts within the principles of the present disclosure, up to and including the full extent established by the broad general meaning of the terms used in the claims. It will therefore be appreciated that the embodiments described above may be modified within the scope of the claims.

1. A circuit board for radio transceiving comprising:
a flexible base having a first conductive hole;
an inductance unit comprising:
a first inductance coil at a first side of the flexible base and surrounding the first conductive hole and extending in a spiral direction and turn-by-turn into the first conductive hole, and a second inductance coil located at an opposite side of the flexible base from the first inductance coil and surrounding the first conductive hole and extending in a spiral direction and turn-by-turn out from the first conductive hole, the first inductance coil and the second inductance coil electrically connected with each other via the first conductive hole through the flexible base.

2. The circuit board of claim 1, further comprising a first copper ground and a second copper ground, wherein the first copper ground, the second copper ground, and the first inductance coil are located at a same side of the flexible base, the first inductance coil and the first copper ground are electrically connected with each other, and the second inductance coil and the second copper ground are electrically connected with each other via a second conductive hole through the flexible base.

3. The circuit board of claim 2, wherein the first inductance coil comprises a first pad, a first connecting portion, a first coil body, and a first ground portion, the first pad is electrically connected with the first conductive hole, the first connecting portion is electrically connected between the first pad and the first coil body, the first ground portion is electrically connected between the first copper ground and an end of the first coil body away from the first connecting portion, and the first coil body extends in a spiral direction and turn-by-turn from the first ground portion into the first connecting portion.

4. The circuit board of claim 3, wherein the first pad is located at a center of the first coil body.

5. The circuit board of claim 3, wherein the first connecting portion is perpendicularly connected between the first pad and the first coil body.

6. The circuit board of claim 3, wherein the first ground portion is perpendicularly connected between the first copper ground and an end of the first coil body away from the first connecting portion.

7. The circuit board of claim 3, wherein a distance along a direction perpendicular to a extension direction of the first connecting portion, between an inner circle of the first coil body and the first pad, is greater than that along the extension direction of the first connecting portion.

8. The circuit board of claim 3, wherein the second inductance coil comprises a second pad, a second connecting portion, a second coil body, a second ground portion, and a ground pad, the second pad is electrically connected to the first pad via the first conductive hole, the second connecting portion is electrically connected between the second pad and the second coil body, the second coil body surrounds the second pad and extends in a spiral direction and turn-by-turn out from the second connecting portion to the second ground portion, the second ground portion is electrically connected between the ground pad and an end of the second coil body away from the second connecting portion, and the ground pad is electrically connected to the second copper ground via the second conductive hole.

9. The circuit board of claim 8, wherein the second pad is located at a center of the second coil body.

10. The circuit board of claim 8, wherein the second connecting portion is perpendicularly connected between the second pad and the second coil body.

11. The circuit board of claim 8, wherein the second ground portion is perpendicularly connected between the ground pad and an end of the second coil body away from the second connecting portion.

12. The circuit board of claim 8, wherein a number of windings of the first coil body is equal to a number of windings of the second coil body.

13. The circuit board of claim 8, wherein a projection of the first coil body to the second coil body is coincided with the second coil body.

14. The circuit board of claim 8, wherein a projection of the outlines of the first coil body substantially coincides with the outlines of the second coil body.

15. The circuit board of claim 1, wherein directions of current flow in the first inductance coil and in the second inductance coil are the same.

16. A method for manufacturing a circuit board comprising:
forming a first conductive hole in a flexible base to electrically connected a first copper layer and a second copper layer located at opposite sides of the flexible base; and
removing portions of the first copper layer and the second copper layer to form a inductance unit, the inductance unit comprising a first inductance coil and a second inductance coil located at opposite sides of the flexible base, the first inductance coil and the second inductance coil electrically connected with each other via the first conductive hole through the flexible base, the first inductance coil surrounding the first conductive hole and extending in a spiral direction and turn-by-turn into the first conductive hole, and the second inductance coil surrounding the first conductive hole and extending in a spiral direction and turn-by-turn out from the first conductive hole.
